(19) United States
(12) Patent Application Publication
(10) Pub. No.: US 2025/0306084 A1
(43) Pub. Date: Oct. 2, 2025

(54) TEST CHAMBER AND TEST APPARATUS

(71) Applicant: SAMSUNG ELECTRONICS CO., LTD., Suwon-si (KR)

(72) Inventors: Hyunmi HONG, Suwon-si (KR); Dahm YU, Suwon-si (KR); Jaehyun KIM, Suwon-si (KR); Dongho LEE, Suwon-si (KR); Seonmi LEE, Suwon-si (KR)

(73) Assignee: SAMSUNG ELECTRONICS CO., LTD., Suwon-si (KR)

(21) Appl. No.: 18/816,190

(22) Filed: Aug. 27, 2024

(30) Foreign Application Priority Data
Mar. 27, 2024 (KR) 10-2024-0041738

(51) Int. Cl. G01R 31/28

(52) U.S. Cl. CPC G01R 31/2862; G01R 31/2868; G01R 31/2874

(57) ABSTRACT

Provided are a test chamber and a test apparatus. The test chamber includes a rack including a plurality of support portions, arranged to be spaced apart from each other in a first direction of the rack, supporting a plurality of test boards, respectively, to accommodate one of the test boards in a slot defined by adjacent ones of the support portions, an inlet portion disposed on one side of the rack and introducing gas to the test board, and an outlet portion disposed on the other side of the rack, opposite to the one side of the rack, and discharging the gas and a flow guide unit including a first flow guide member disposed to be adjacent to the inlet portion, having a first opening opposing the inlet portion and guiding the gas to flow into the inlet portion.

### CROSS-REFERENCE TO RELATED APPLICATIONS

This application claims the benefit of priority to Korean Patent Application No. 10-2024-0041738, filed on Mar. 27, 2024 in the Korean Intellectual Property Office, the disclosure of which is incorporated herein by reference in its entirety.

### TECHNICAL FIELD

The present inventive concept relates to a test chamber and a test apparatus.

### BACKGROUND

Semiconductor devices that have completed a semiconductor manufacturing process may be tested for reliability through various tests. For example, a burn-in test may be performed to inspect the lifespan and malfunctioning of a semiconductor package in an extreme environment outside of normal operating conditions. Generally, in the burn-in test, thermal stress is applied to a semiconductor device by circulating high or low temperature air within a test chamber in which the semiconductor device to be inspected is accommodated.

Air for applying thermal stress to the semiconductor device is introduced into the test chamber through a supply duct located on the side of the test chamber and supplied to each test board disposed within the test chamber and on which the semiconductor device is supported. During this process, temperature differences may occur between semiconductor devices depending on flow rates of air supplied to each test board and locations of the test boards. In addition, a portion of the air passing through the supply duct may flow around the test chamber, reducing inspection efficiency, and in addition, the flow rate of air inside the test chamber may be reduced, causing problems, such as increasing the temperature difference between semiconductor devices.

### SUMMARY

An aspect of the present inventive concept is to provide a test chamber and a test apparatus capable of reducing a temperature difference between inspection objects.

Another aspect of the present inventive concept is to provide a test chamber and test apparatus capable of preventing gas flow around a rack.

According to an aspect of the present inventive concept, a test chamber includes: a rack including a plurality of support portions, arranged to be spaced apart from each other in a first direction of the rack, supporting a plurality of test boards, respectively, to accommodate one of the test boards in a slot defined by adjacent ones of the support portions, an inlet portion disposed on one side and introducing gas to the test board, and an outlet portion disposed on another side of the rack, opposite to the one side, and discharging the gas; and a flow guide unit including a first flow guide member disposed to be adjacent to the inlet portion, having a first opening opposing the inlet portion and guiding the gas to flow into the inlet portion.

According to another aspect of the present inventive concept, a test chamber includes: a rack including a plurality of support portions arranged to be spaced apart from each other in a first direction of the rack, supporting a plurality of test boards, respectively, to accommodate one of the test boards in a slot defined by adjacent ones of the support portions, an inlet portion disposed on one side and introducing gas to the test board, and an outlet portion disposed on the other side of the rack, opposite to the one side of the rack, and discharging the gas; a flow guide unit including a first flow guide member having a first opening opposite to the inlet portion, disposed to be spaced apart from the inlet portion by a first gap range and guiding the gas to flow into the inlet portion through the first opening, and a second flow guide member having a second opening opposite to the outlet portion, disposed to be spaced apart from the outlet portion by a second gap range and guiding the gas flowing out of the outlet portion to be discharged through the second opening.

According to still another aspect of the present inventive concept, a test apparatus includes: a device body having an internal space; a test chamber disposed in the internal space; a first duct disposed on one side of the test chamber and through which gas flows into the test chamber; a second duct disposed on another side of the test chamber opposite to one side of the test chamber and through which the gas is discharged from the test chamber; a blowing unit for generating a flow of the gas; and a temperature control unit for controlling a temperature of the gas, wherein the test chamber includes: a rack including a plurality of support portions arranged to be spaced apart from each other in a first direction of the rack and supporting a plurality of test boards, respectively, to accommodate one of the test boards in a slot defined by adjacent ones of the support portions, an inlet portion disposed on one side of the rack and introducing the gas to the test boards, and an outlet portion disposed on another side of the rack, opposite to the one side of the rack, and discharging the gas; and a flow guide unit including a first flow guide member disposed between the first duct and the inlet portion, having a first opening opposite to the inlet portion, and guiding the gas to flow into the inlet portion through the first opening and a second flow guide member disposed between the outlet portion and the second duct, having a second opening opposite to the outlet portion, and guiding the gas flowing out of the outlet portion to be discharged to the second duct.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram illustrating a partial configuration of the related art test chamber;

FIG. 2 is a diagram illustrating a test apparatus according to an exemplary embodiment of the present inventive concept;

FIG. 3 is a diagram illustrating a partial configuration of a test chamber according to an exemplary embodiment of the present inventive concept;

FIG. 4 is a diagram illustrating a rack of a test chamber according to an exemplary embodiment of the present inventive concept;

FIG. 5 is a side view illustrating a rack and a flow guide unit of a test chamber according to an exemplary embodiment of the present inventive concept;

FIG. 6 is a plan view illustrating a rack and a flow guide unit of a test chamber according to an exemplary embodiment of the present inventive concept; and

FIG. 7 is a diagram illustrating a rack of a test chamber according to another exemplary embodiment of the present inventive concept.

### DETAILED DESCRIPTION

Hereinafter, exemplary embodiments of the present inventive concept are described with reference to the accompanying drawings.

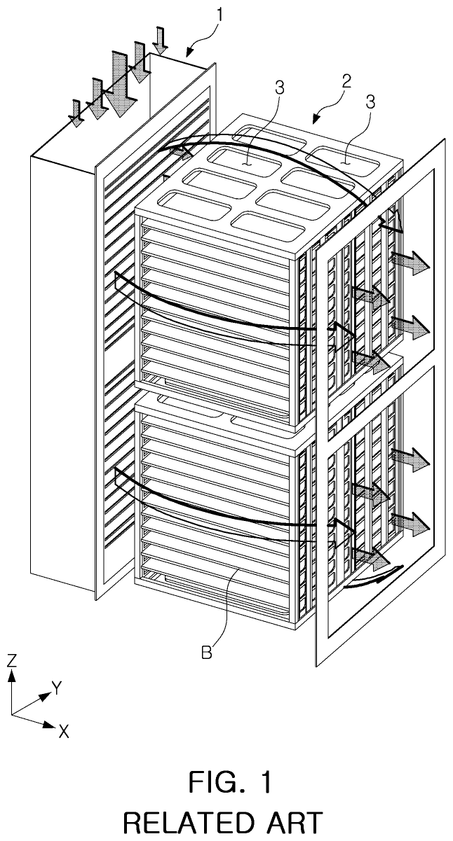

FIG. 1 is a diagram illustrating a partial configuration of the related art test chamber.

Referring to FIG. 1, the related art test chamber adopts a structure in which an inlet duct 1 through which gas flows is spaced apart from one side of a rack 2 by a certain gap, so a bypass phenomenon in which a portion of gas passing through the inlet duct 1 flows around the rack 2 may occur. In particular, since a plurality of openings 3 are formed on top of the rack 2, gas passing through a test board B located at the uppermost end inside the rack 2 and supporting inspection objects may flow upwardly of the rack 2 to cause a flow bypass phenomenon, which increases a temperature difference between the test boards B, thereby deteriorating test reliability.

In order to solve the above problems, the present inventive concept provides a test apparatus as described below with reference to the drawings.

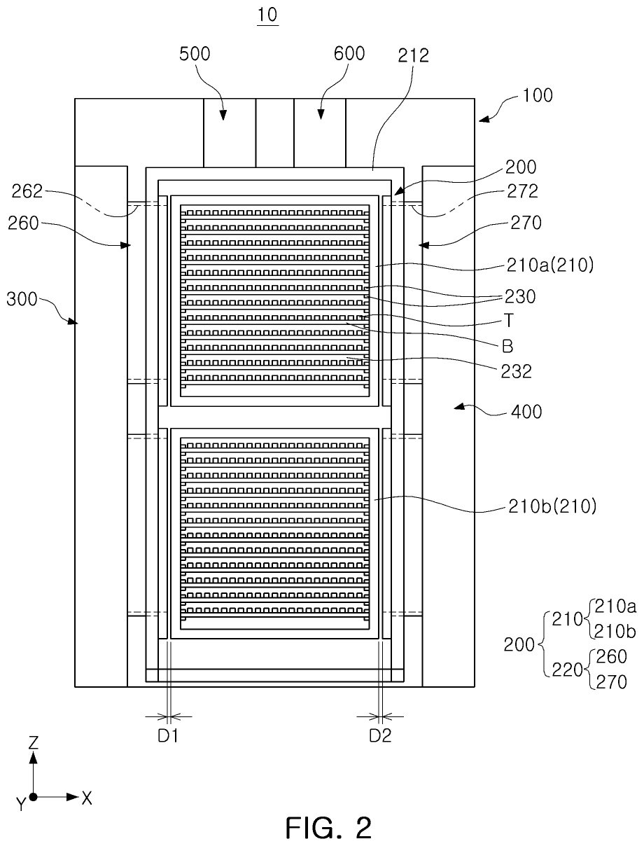

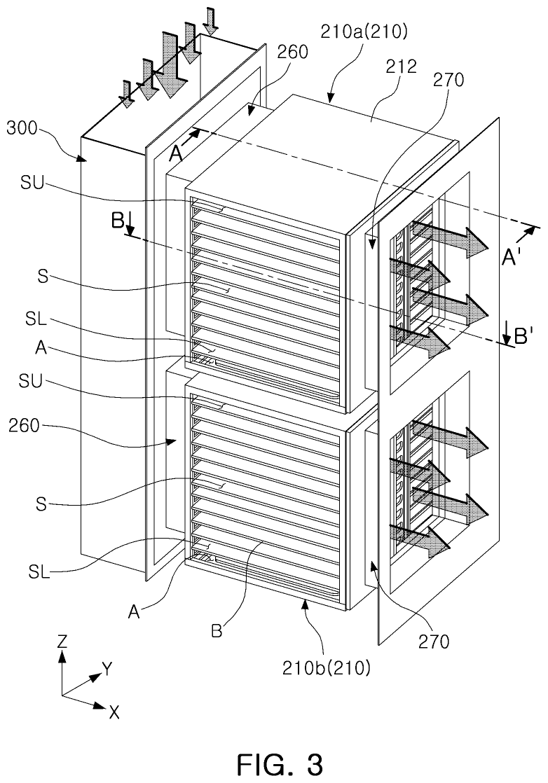

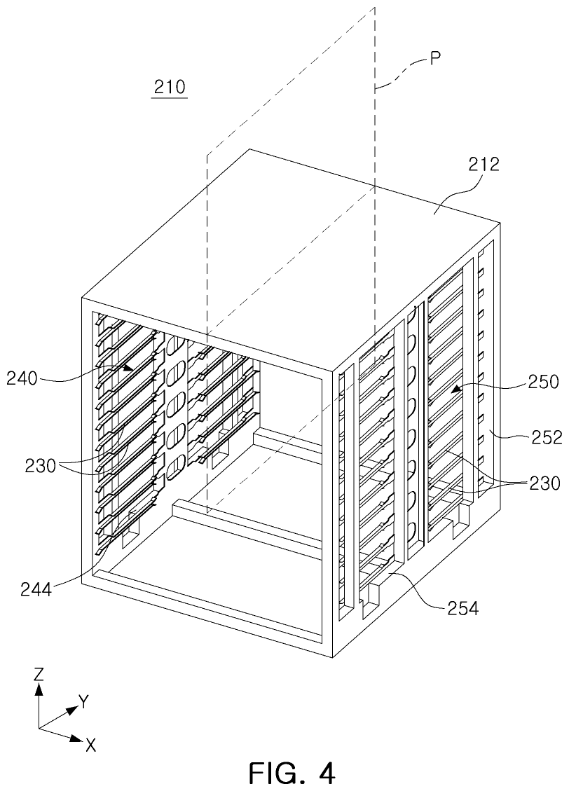

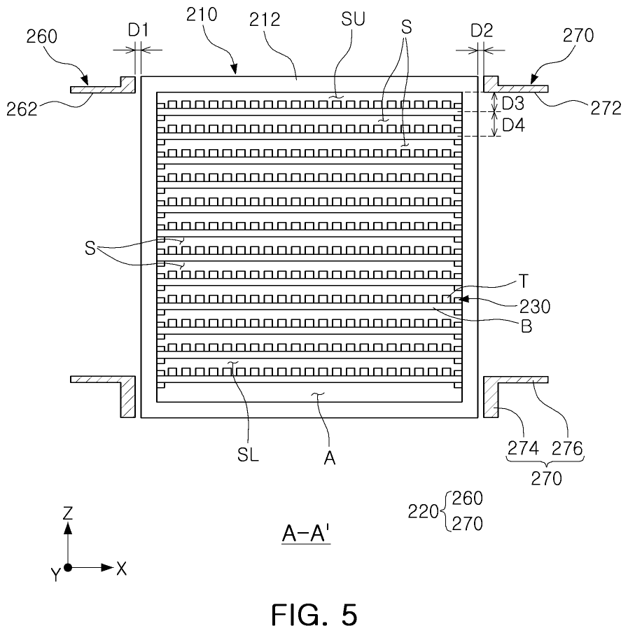

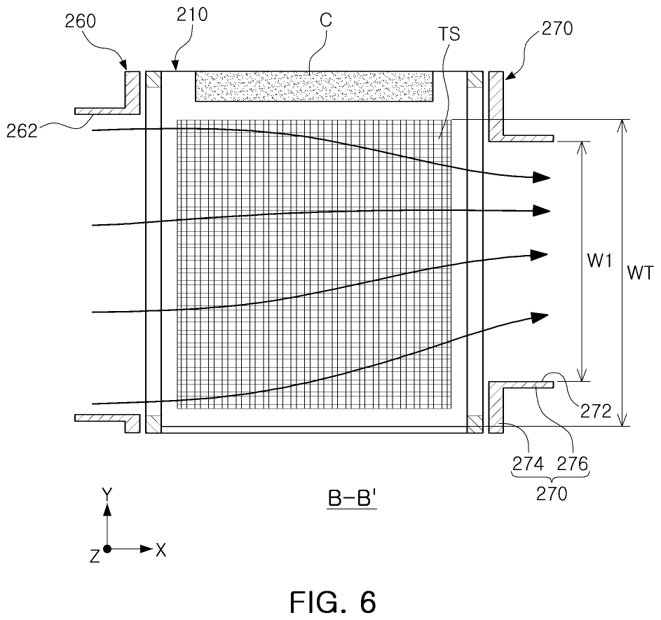

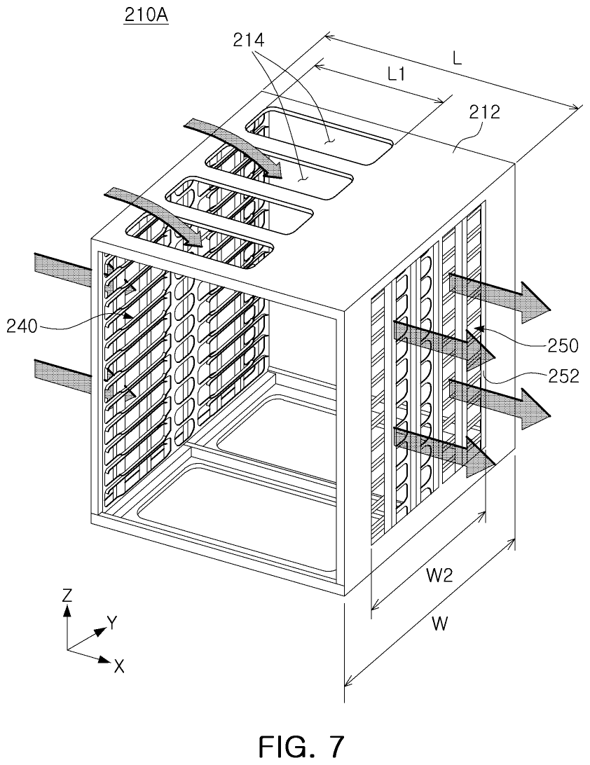

FIG. 2 is a diagram illustrating a test apparatus according to an exemplary embodiment of the present inventive concept, FIG. 3 is a diagram illustrating a partial configuration of a test chamber according to an exemplary embodiment of the present inventive concept, FIG. 4 is a diagram illustrating a rack of a test chamber according to an exemplary embodiment of the present inventive concept, FIG. 5 is a side view illustrating a rack and a flow guide unit of a test chamber according to an exemplary embodiment of the present inventive concept, FIG. 6 is a plan view illustrating a rack and a flow guide unit of a test chamber according to an exemplary embodiment of the present inventive concept, and FIG. 7 is a diagram illustrating a rack of a test chamber according to another exemplary embodiment of the present inventive concept.

Referring to FIG. 2, a test apparatus 10 according to an exemplary embodiment includes a device body 100 having an internal space, a test chamber 200, a first duct 300, a second duct 400, and a blowing unit 500, and a temperature control unit 600.

The test chamber 200 may be provided as a burn-in test chamber disposed in the internal space of the device body 100 and testing thermal stress of a semiconductor device on which a semiconductor package process has been completed as an inspection object T. However, the test chamber of the present inventive concept is not limited thereto and may be applied to various devices that may test the strength and stability of the inspection object T by performing various heat damage tests on the inspection object T at high and low temperatures. Here, the inspection object T may include a semiconductor package completed through a semiconductor manufacturing process and a packaging process, and a plurality of semiconductor packages may be arranged on the test board B. The inspection object T may be inserted into a connection socket (not illustrated) provided on an upper surface of the test board B and connected to a circuit pattern inside the test board B. A connector C connected to the circuit pattern may be disposed on one side of the test board B and may inserted into a connection socket (not illustrated) disposed on one side of the device body 100 to be connected. Accordingly, an inspection signal applied to the connection socket inside the device body 100 may be applied to the inspection object T through the connector C and circuit pattern of the test board B.

The first duct 300 may be disposed on one side of the test chamber 200 and allows gas to flow into the test chamber 200. Gas may flow into the test board B, which is supported on a rack 210 to be described below in the test chamber 200 and on which the inspection object T is disposed, through the first duct 300, and thus, the inspection object T may be tested for heat stress. In an exemplary embodiment, in order to uniformly introduce gas into the plurality of test boards B supported on the rack 210 in the test chamber 200, a manifold (not illustrated) or a wind deflector (not illustrated) performing a function of uniformly distributing gas introduced into the test board B within the test chamber 200 may be disposed in the first duct 300.

The second duct 400 is disposed on the other side of the test chamber 200 opposite to one side of the test chamber 200 and allows gas to be discharged from the test chamber 200. Gas that has passed the plurality of test boards B supported on the rack 210 in the test chamber 200 may be discharged to the outside of the test chamber 200 through the second duct 400.

The blowing unit 500 may generate a flow of the gas. In an exemplary embodiment, the blowing unit 500 may include a blowing fan and a flow of gas may be generated so that the gas circulates in the test chamber 200 by the operation of the blowing unit 500.

The temperature control unit 600 may control a temperature of the gas. The temperature control unit 600 may perform various tests, such as a high temperature test or a low temperature test, by adjusting the temperature of the gas to desired test conditions as needed.

Referring to FIGS. 2 to 6, the test chamber 200 may include the rack 210 and a flow guide unit 220.

The rack 210 may be detachably disposed in the internal space of the test chamber 200 and may have a first direction Z, a second direction Y, and a third direction X. The first direction Z of the rack 210 may refer to a height direction of the rack 210 and may be a vertical direction as illustrated in FIG. 1. The second direction Y of the rack 210 may refer to a direction, perpendicular to the first direction Z, may be a front-back direction as illustrated in FIG. 1, and may be a direction, perpendicular to a flow direction from an inlet portion 240 to an outlet portion 250 of the rack 210 to be described below. The third direction X of the rack 210 may refer to a direction, perpendicular to the first direction Z and the second direction Y, may be a left-right direction as illustrated in FIG. 1, and may be a direction in accordance with the flow direction from the inlet portion 240 to the outlet portion 250 of the rack 210 to be described below.

In an exemplary embodiment, a plurality of racks 210 may be arranged in the first direction Z in the internal space of the test chamber 200. In an exemplary embodiment, as illustrated in FIGS. 2 and 3, a first rack 210a may be disposed at the top and a second rack 210b may be disposed at the bottom in the first direction Z in the internal space of the test chamber 200. The first rack 210a and the second rack 210b may have the same structure, and a plurality of test boards B may be supported on each of the racks 210a and 210b. The test boards B may be supported in a sequentially stacked form in the first direction Z of the test chamber 200 through the first rack 210a and the second rack 210b.

The rack 210 may include a plurality of support portions 230, the inlet portion 240, and the outlet portion 250.

The plurality of support portions 230 may be spaced apart from each other in the first direction Z of the rack 210 with a slot S accommodating the test board B therebetween. That is, a space between the support portions 230 adjacent to each other in the first direction Z of the rack 210 may be provided as a slot S for accommodating each test board B. A plurality of test boards B supporting a plurality of inspection objects T may be supported on the plurality of support portions 230. With a plurality of test boards B supported on the support portions 230, respectively, each test board B may be accommodated in each corresponding slot S. In an exemplary embodiment, each support portion 230 may be formed in the form of a protruding guide supporting both edges of the test board B.

The inlet portion 240 may be disposed on one side of the rack 210 and may introduce gas into the test board B supported on each support portion 230. The inlet portion 240 may be disposed to be adjacent to the first duct 300. The outlet portion 250 may be disposed on the other side opposite to one side of the rack 210 and may discharge gas. The outlet portion 250 may be disposed to be adjacent to the second duct 400. The inlet portion 240 and the outlet portion 250 of the rack 210 may be disposed to face each other in the third direction X.

The flow guide unit 220 may include a first flow guide member 260 and a second flow guide member 270.

The first flow guide member 260 may be disposed between the first duct 300 and the inlet portion 240 of the rack 210 and has a first opening 262 facing the inlet portion 240. The first flow guide member 260 may guide gas that has passed through the first duct 300 to flow into the inlet portion 240 of the rack 210 through the first opening 262. By guiding gas to flow into the test chamber 200 through the first flow guide member 260, air flow around the test chamber 200 may be reduced, and further, a deviation of a temperature and a flow velocity of gas inside the test chamber 200 may be reduced. The first flow guide member 260 may be mounted on one sidewall of the test chamber 200. In an exemplary embodiment, the first flow guide member 260 may have a rectangular shape surrounding the first opening 262. However, without being limited thereto, the first flow guide member 260 may have various shapes having a configuration in which gas is introduced into the inlet portion 240 of the rack 210. In an exemplary embodiment, as illustrated in FIG. 5, a lower end surface of the first opening 262 of the first flow guide member 260 may be located on substantially the same level as that of the slot SL located at the bottom in the first direction Z. That is, the lower end surface of the first opening 262 of the first flow guide member 260 may be located on substantially the same level as that of the test board B located at the bottom in the first direction Z. Through the first flow guide member 260, it is possible to prevent gas from being bypassed into a space A below the test board B located at the bottom of the rack 210 and flow loss of gas passing through the entire test board B may be reduced. However, the present inventive concept is not limited thereto, and the first opening 262 of the first flow guide member 260 may be located on a level between upper and lower end surfaces of the test board B located at the bottom in the first direction Z.

As used herein, the expression “substantially the same level” may refer to being at the same height level relative to the height level compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

One side of the first flow guide member 260 may be connected to the first duct 300 and the other side thereof may be disposed to be adjacent to the inlet portion 240 of the rack 210. In an exemplary embodiment, as illustrated in FIG. 5, the inlet portion 240 of the rack 210 and the first flow guide member 260 may be arranged to be spaced apart from each other by a first gap range D1. In an exemplary embodiment, the first gap range D1 may be 0 mm<D1≤20 mm. Since the inlet portion 240 of the rack 210 and the first flow guide member 260 are arranged to be spaced apart from each other by the first gap range D1, when the rack 210 is mounted or removed from the test chamber 200, detachment and attachment operations may be easily performed without movement interference with the flow guide member 260. Meanwhile, when the gap between the inlet portion 240 of the rack 210 and the first flow guide member 260 exceeds 20 mm, a portion of the gas that has passed through the first flow guide member 260 may leak to the outside of the inlet portion 240 of the rack 210, which may cause problems, such as an increase in temperature difference between the test boards B.

The second flow guide member 270 may be disposed between the outlet portion 250 of the rack 210 and the second duct 400 and may have a second opening 272 facing the outlet portion 250. The second flow guide member 270 may guide gas flowing out from the outlet portion 250 of the rack 210 to be discharged into the second duct 400. The second flow guide member 270 may be mounted on the other sidewall of the test chamber 200. In an exemplary embodiment, the second flow guide member 270 may be formed in a rectangular shape surrounding the second opening 272. However, without being limited thereto, the second flow guide member 270 may have various shapes having a configuration in which gas passing through the outlet portion 250 of the rack 210 flows out to the second duct 400. In the present exemplary embodiment, as illustrated in FIG. 5, a lower end surface of the second opening 272 of the second flow guide member 270 may be located on substantially the same level as that of the slot SL located at the bottom in the first direction Z. That is, the lower end surface of the second opening 272 of the second flow guide member 270 may be located on substantially the same level as that of the test board B located at the bottom in the first direction Z. However, the present inventive concept is not limited thereto, and the second opening 272 of the second flow guide member 270 may be located on a level between the upper and lower end surfaces of the test board B located at the bottom in the first direction Z.

One side of the second flow guide member 270 may be disposed to be adjacent to the outlet portion 250 of the rack 210, and the other side thereof may be connected to the second duct 400. In an exemplary embodiment, as illustrated in FIG. 5, the outlet portion 250 of the rack 210 and the second flow guide member 270 may be arranged to be spaced apart from each other by a second gap range D2. In an exemplary embodiment, the second gap range D2 may be 0 mm<D2≤20 mm. Since the outlet portion 250 of the rack 210 and the second flow guide member 270 are arranged to be spaced apart from each other by the second gap range D2, when the rack 210 is mounted on or removed from the test chamber 200, detachment and attachment operations may be easily performed without movement interference with the second flow guide member 270.

In an exemplary embodiment, as illustrated in FIGS. 5 and 6, the second flow guide member 270 may include a blocking wall 274 shielding the edge portion of the outlet portion 250 of the rack 210 and a discharge portion 276 connected to one side of the blocking wall 274 and in which the second opening 272 is formed. The second opening 272 of the second flow guide member 270 may have a first width W1 in the second direction Y of the rack 210. The first width W1 of the second opening 272 may be smaller than or equal to a width WT in the second direction Y in the test region TS of the test board B. Here, the test region TS of the test board B refers to a region in which the inspection object T is located. In an exemplary embodiment, the first width W1 of the second opening 272 may be set to be smaller than the width WT in the test region TS of the test board B in the second direction Y. Accordingly, as illustrated in FIG. 6, by narrowly limiting a flow area of gas passing through the discharge portion 276 of the second flow guide member 270, gas passing through the inside of the rack 210 may be collected to the test region TS of each test board B, while flowing toward the outlet portion 250, thereby improving flow concentration of gas. In an exemplary embodiment, a ratio of the first width W1 of the second opening 272 to the width WT in the second direction Y in the test region TS of the test board B may be 0.5≤W1/WT≤1.

Meanwhile, in an exemplary embodiment, as illustrated in FIG. 7, the outlet portion 250 of the rack 210A may include an outlet 252 having a second width W2 in the first direction Z and the second direction Y. In an exemplary embodiment, the ratio of the second width W2 of the outlet 252 to the width W of the rack 210A in the second direction Y may be 0.5≤W2/W≤1. Accordingly, by limiting the second width W2 of the outlet 252 of the rack 210A, gas passing through the inside of the rack 210 may be collected to the test region TS of each test board B, while flowing toward the outlet portion 250, thereby improving flow concentration of gas.

Meanwhile, one of the first width W1 of the second opening 272 of the second flow guide member 270 and the second width W2 of the outlet 252 of the outlet portion 250 of the racks 210 and 210A may be selectively limited. In an exemplary embodiment, the ratio of the first width W1 of the second opening 272 to the width WT in the second direction Y in the test region TS of the test board B may be set to 0.5≤W1/WT≤1, or the ratio of the second width W2 of the outlet 252 to the width W of the racks 210 and 210A in the second direction Y may be set to 0.5≤W2/W≤1. Accordingly, by narrowly limiting the first width W1 of the second opening 272 of the second flow guide member 270 or the second width W2 of the outlet 252 of the outlet portion 250 of the racks 210 and 210A, gas passing through the inside of the rack 210 may be collected to the test region TS of each test board B, while flowing toward the outlet portion 250.

In an exemplary embodiment, as illustrated in FIG. 7, the second width W2 of the outlet 252 of the outlet portion 250 may be configured to be smaller than or equal to the width WT in the second direction Y in the test region TS of the test board B. In this case, the ratio of the second width W2 of the outlet 252 to the width WT in the second direction Y in the test region TS of the test board B may be 0.5≤W2/WT≤1.

In an exemplary embodiment, shielding portions 244 and 254 having an upper end surface located on substantially the same level as that of the slot SL located at the bottom in the first direction Z may be arranged at a lower end of the inlet portion 240 and a lower end of the outlet portion 250 of the rack 210, respectively. That is, the upper end surfaces of the shielding portions 244 and 254 may be located on substantially the same level as that of the test board B located at the bottom in the first direction Z. The configuration of the shielding portions 244 and 254 may prevent gas from being bypassed into the lower space A of the test board B located at the bottom of the rack 210 and reduce gas flow loss.

In addition, the upper end portions 212 of the racks 210 and 210A may have a plate shape with at least a portion thereof blocked.

In an exemplary embodiment, as illustrated in FIG. 4, the upper end portion 212 of the rack 210 may be formed to have a plate shape entirely blocked. As illustrated in FIG. 5, a gap D3 between the upper end portion 212 of the rack 210 and the support portion 230 adjacent to the upper end portion 212 in the first direction Z may be substantially same as a gap D4 between two support portions 230 adjacent to each other. Accordingly, the uppermost slot SU located between the upper end portion 212 of the rack 210 and the support portion 230 adjacent to the upper end portion 212 in the first direction Z may have substantially the same height as the slot S located between two support portions 230 adjacent to each other.

In an exemplary embodiment, as illustrated in FIG. 4, the rack 210 may have a structure symmetrical based on a virtual vertical plane P which passes through the center of the rack 210 and extends in the first direction Z and the second direction Y. In this case, the upper end portion 212 of the rack 210 may be formed in the form of an entirely blocked plate, and the inlet portion 240 and the outlet portion 250 of the rack 210 may be symmetrical with respect to the virtual vertical plane P. By applying the symmetrical structure of the rack 210, the chamber may be used as a left and right shared chamber, regardless of a gas flow direction, without separately distinguishing between the inlet portion 240 and the outlet portion 250. However, the present inventive concept is not limited thereto, and the rack may have an asymmetric structure as needed.

In another exemplary embodiment, the rack 210A may have a plate shape in which the upper portion 212 thereof is partially blocked as illustrated in FIG. 7. In this case, the upper end portion 212 of the rack 210A may have a plate shape in which an opening 214 is formed in an inflow portion adjacent to the inlet portion 240 and an outflow portion adjacent to the outlet portion 250 is blocked. The ratio of a length L1 of the opening 214 to a length L of the rack 210A in the third direction X of the rack 210A may be 0≤L1/L≤1. A case in which the ratio of the length L1 of the opening 214 to the length L of the rack 210A in the third direction X of the rack 210A is 0 refers to a structure in which the upper end portion 212 of the rack 210A has an entirely blocked plate shape without an opening. Through the structure in which the opening 214 is formed at the inflow portion of the upper end portion 212 adjacent to the inlet portion 240, gas around the inlet portion 240 of the rack 210A may flow into the rack 210A through the opening 214, thereby increasing an overall flow rate of gas flowing into the rack 210A, and through the structure in which the outflow portion of the upper end portion 212 of the rack 210A adjacent to the outlet portion 250 is blocked, outflow of gas from the inside to the outside of the rack 210A may be effectively prevented.

The present inventive concept may provide the test chamber and the test apparatus capable of minimizing gas flow around the rack and guide gas to flow inside the rack through the configuration of the flow guide unit, thereby reducing a temperature difference between inspection objects.

The present inventive concept may provide the test chamber and the test apparatus capable of improving test reliability by reducing a temperature difference between inspection objects through the configuration of the inlet portion, the outlet portion, and upper end portion of the rack.

The present inventive concept may provide the test chamber and the test apparatus capable of reducing a temperature difference between inspection objects.

In addition, the present inventive concept may provide the test chamber and the test apparatus capable of preventing gas flow around the rack.

While exemplary embodiments have been illustrated and described above, it will be apparent to those skilled in the art that modifications and variations could be made without departing from the scope of the present inventive concept as defined by the appended claims.

What is claimed is:

1. A test chamber comprising:
a rack including a plurality of support portions, arranged to be spaced apart from each other in a first direction of the rack, supporting a plurality of test boards, respectively, to accommodate one of the test boards in a slot defined by adjacent ones of the support portions, the rack further including an inlet portion disposed on one side of the rack and introducing gas to the test boards, and an outlet portion disposed on another side of the rack, opposite to the one side of the rack, and discharging the gas; and
a flow guide unit including a first flow guide member disposed to be adjacent to the inlet portion, having a first opening opposing the inlet portion and guiding the gas to flow into the inlet portion.

2. The test chamber of claim 1, wherein a lower end surface of the first opening is located on substantially the same level as that of a slot defined by two bottommost support portions in the first direction among the plurality of support portions.

3. The test chamber of claim 1, wherein the inlet portion and the first flow guide member are arranged to be spaced apart from each other by a first gap range D1.

4. The test chamber of claim 3, wherein the first gap range D1 is 0 mm<D1≤20 mm.

5. The test chamber of claim 1, wherein
the flow guide unit includes a second flow guide member disposed to be adjacent to the outlet portion and guiding the gas flowing out of the outlet portion to be discharged, and
the second flow guide member has a second opening opposite to the outlet portion.

6. The test chamber of claim 5, wherein the second opening has a first width W1 in a second direction of the rack, perpendicular to the first direction and a flow direction from the inlet portion to the outlet portion, and the first width W1 is smaller than a width WT in the second direction in a test region of one of the test boards on which an inspection object is located.

7. The test chamber of claim 6, wherein a ratio of the first width W1 to the width WT in the second direction in the test region of the test board is 0.5≤W1/WT≤1.

8. The test chamber of claim 5, wherein a lower end surface of the second opening is located on substantially the same level as that of a slot defined by two bottommost support portions in the first direction among the plurality of support portions.

9. The test chamber of claim 5, wherein the outlet portion and the second flow guide member are arranged to be spaced apart from each other by a second gap range D2.

10. The test chamber of claim 9, wherein the second gap range D2 is 0 mm<D2≤20 mm.

11. The test chamber of claim 1, wherein an upper end portion of the rack has a plate shape with at least a portion blocked.

12. The test chamber of claim 11, wherein the upper end portion of the rack has an inflow portion, in which at least one opening is formed, adjacent to the inlet portion and an outflow portion, which is blocked, adjacent to the outlet portion.

13. The test chamber of claim 1, wherein a ratio of a length L1 of an opening formed at an upper end portion of the rack to a length L of the rack in a flow direction from the inlet portion to the outlet portion is 0≤L1/L≤1.

14. The test chamber of claim 1, wherein at least one shielding portion having an upper end surface located on substantially the same level as that of a slot defined by two bottommost support portions in the first direction among the plurality of support portions is disposed at a lower end of the inlet portion and/or a lower end of the outlet portion.

15. The test chamber of claim 1, wherein the outlet portion includes an outlet having a second width W2 in a second direction of the rack, perpendicular to the first direction and a flow direction from the inlet portion to the outlet portion, and a ratio of a second width W2 to a width W of the rack in the second direction is 0.5≤W2/W≤1.

16. The test chamber of claim 11, wherein an upper end portion of the rack has an entirely blocked plate shape, and the rack has a symmetrical structure based on a virtual vertical plane which passes through a center of the rack in a flow direction from the inlet portion to the outlet portion and extends in the first direction and a second direction of the rack, perpendicular to the first direction and the flow direction.

17. The test chamber of claim 1, wherein a gap between the upper end portion of the rack and one of the support portions adjacent to the upper end portion in the first direction is substantially same as a gap between two of the support portions adjacent to each other.

18. A test chamber comprising:
a rack including a plurality of support portions, arranged to be spaced apart from each other in a first direction of the rack, supporting a plurality of test boards, respectively, to accommodate one of the test boards in a slot defined by adjacent ones of the support portions, the rack further including an inlet portion disposed on one side of the rack and introducing gas to the test boards, and an outlet portion disposed on another side of the rack, opposite to the one side of the rack, and discharging the gas;
a flow guide unit including a first flow guide member having a first opening opposite to the inlet portion, disposed to be spaced apart from the inlet portion by a first gap range and guiding the gas to flow into the inlet portion through the first opening, and a second flow guide member having a second opening opposite to the outlet portion, disposed to be spaced apart from the outlet portion by a second gap range and guiding the gas flowing out of the outlet portion to be discharged through the second opening.

19. The test chamber of claim 18, wherein
the second opening has a first width W1 in a second direction of the rack, perpendicular to the first direction and a flow direction from the inlet portion to the outlet portion,
the outlet portion includes an outlet having a second width W2 in the second direction of the rack, and
any one of the first width W1 or the second width W2 is smaller than or equal to a width W in the second direction in a test region of one of the test boards on which an inspection object is located.

20. A test apparatus comprising:
a device body having an internal space;
a test chamber disposed in the internal space;
a first duct disposed on one side of the test chamber and through which gas flows into the test chamber;
a second duct disposed on another side of the test chamber opposite to one side of the test chamber and through which the gas is discharged from the test chamber;
a blowing unit configured to generate a flow of the gas; and
a temperature control unit configured to control a temperature of the gas,
wherein the test chamber includes:
a rack including a plurality of support portions arranged to be spaced apart from each other in a first direction of the rack, supporting a plurality of test boards, respectively, to accommodate one of the test boards in a slot defined by adjacent ones of the support portions, the rack further including an inlet portion disposed on one side of the rack and introducing the gas to the test boards, and an outlet portion disposed on another side of the rack, opposite to the one side of the rack, and discharging the gas; and
a flow guide unit including a first flow guide member disposed between the first duct and the inlet portion, having a first opening opposite to the inlet portion, and guiding the gas to flow into the inlet portion through the first opening, and a second flow guide member disposed between the outlet portion and the second duct, having a second opening opposite to the outlet portion, and guiding the gas flowing out of the outlet portion to be discharged to the second duct.
